(19) United States
(12) Patent Application Publication
(10) Pub. No.: US 2026/0343778 A1
(43) Pub. Date: Oct. 29, 2026

(54) INCREASING SPEED AND EFFICIENCY IN AI ACCELERATOR RACKS WITH A FIXED COMMUNICATION TOPOLOGY

(71) Applicant: Microsoft Technology Licensing, LLC, Redmond, WA (US)

(72) Inventor: Nitin BHARDWAJ, Redmond, WA (US)

(21) Appl. No.: 19/190,380

(22) Filed: Apr. 25, 2025

(51) Int. Cl. H05K 7/14; G11C 7/10

(52) U.S. Cl. CPC H05K 7/1489; G11C 7/1012; H05K 7/1491

(57) ABSTRACT

The present disclosure generally relates to computer hardware, configurations, and methods for increasing the speed and efficiency in artificial intelligence (AI) accelerator racks with a fixed communication topology. For example, the computer hardware, configurations, and methods described herein replace the network switch typically included in an AI accelerator rack with crossbar switches that are added to trays of AI accelerators within the rack. One or more embodiments can include a tray of AI accelerators with both a y-dimension crossbar switch and an x-dimension crossbar switch. Both the y-dimension crossbar switch and the x-dimension crossbar switch may be configured to a fixed AI model communication topology that enable the AI accelerators within the tray to communicate rapidly across the y-dimension crossbar switch and the x-dimension crossbar switch with very little power expenditure. Additionally, an AI accelerator rack can include additional z-dimension crossbar switches across trays of AI accelerators.

### BACKGROUND

In high performance computing environments, specialized computing devices are typically housed in rack structures. For example, a rack may house multiple artificial intelligence (AI) accelerators, which are optimized for various parallel processing tasked required by AI algorithms. Often, such racks include a network switch that serves to connect the devices within the rack. For example, a typical AI accelerator rack may include a PCIe switch that is designed to handle high bandwidth traffic from the devices within the rack. While such switches may facilitate efficient data ingestion and distribution, they are often physically large and power-hungry-as well as being heavily reliant on software to effectively route data among the various devices within the rack.

The subject matter in the background section is intended to provide an overview of the overall context for the subject matter disclosed herein. The subject matter discussed in the background section should not be assumed to be prior art merely as a result of its mention in the background section. Similarly, a problem mentioned in the background section or associated with the subject matter of the background section should not be assumed to have been previously recognized in the prior art.

### BRIEF DESCRIPTION OF THE DRAWINGS

FIG. 1 illustrates an overview of a prior art AI accelerator tray.

FIG. 2 illustrates an overview of an AI accelerator tray featuring both x-dimension and y-dimension crossbar switches in accordance with one or more embodiments.

FIGS. 3A and 3B illustrate overviews of an AI accelerator rack featuring a z-dimension crossbar switch in addition to x-dimension and y-dimension crossbar switches in accordance with one or more embodiments.

FIG. 4 illustrates a series of acts for configuring an AI accelerator rack in accordance with one or more embodiments.

FIG. 5 illustrates certain components that may be included within a computer system in accordance with one or more embodiments.

### DETAILED DESCRIPTION

The present disclosure relates to computer hardware, configurations, and methods for increasing the speed and efficiency in artificial intelligence (AI) accelerator racks with a fixed communication topology. As mentioned above, typical AI accelerator racks include a single switch that routes data signals among the accelerators within the rack. These switches route data signals according to software instructions that are specific to the model being run by the accelerators. While such switches perform with speed and accuracy, they often consume large amounts of power as well as take up large amounts of rack space.

To avoid these problems, the computer hardware, configurations, and methods described herein include replacing the network switch typically included in an AI accelerator rack with crossbar switches that are added to trays of AI accelerators within the rack. As will be discussed in greater detail below, the embodiments discussed herein include a tray of AI accelerators with both a y-dimension crossbar switch and an x-dimension crossbar switch. Both the y-dimension crossbar switch and the x-dimension crossbar switch are configured to a fixed AI model communication topology that enable the AI accelerators within the tray to communicate rapidly across the y-dimension crossbar switch and the x-dimension crossbar switch with very little power expenditure. In additional embodiments discussed herein, an AI accelerator rack can include additional z-dimension crossbar switches across trays of AI accelerators to further enhance the computing power of the rack. For example, and as will be discussed in greater detail below, the embodiments discussed herein enable full injection bandwidth across multiple AI accelerators while generally minimizing the hop count between AI accelerators.

As such, the computer hardware, configurations, and methods described herein provide improved power efficiency over existing network switch-based rack configurations. To illustrate, the crossbar switches utilized by the computer hardware, configurations, and methods described herein can include serializer/deserializer (SerDes) crossbars that are designed to manage dataflow between multiple ports. These SerDes crossbars are configured as part of a co-design with the computational model that will be run by the tray, rack, or racks of AI accelerators. As such, the crossbars act as high-speed data transfer mediums among the AI accelerators without the need for any controlling software. Because of this, the crossbars consume very little power while enabling the same high-speed data communication provided by the power-hungry, software-controlled network switches typically used in AI accelerator racks.

Additionally, the computer hardware, configurations, and methods described herein save physical space within an AI accelerator rack. As mentioned above, typical network switches included in most AI accelerator racks are physically inefficient as they are large and take up a prohibitive amount of space within the limited special constraints of conventional AI accelerator racks. It follows that each AI accelerator rack is limited to a certain number of AI accelerator trays to accommodate the size of the network switch. Conversely, the computer hardware, configurations, and methods described herein move this functionality into each AI accelerator tray—freeing up space within each rack that can be used to increase the number of trays held by the rack.

Moreover, in addition to the computational and physical efficiencies presented above, the computer hardware, configurations, and methods described herein also provide additional cost savings over typical AI accelerator rack systems. For example, network switches utilized by typical AI accelerator racks generally carry a high price tag. The crossbar switches utilized by the computer hardware, configurations, and methods described herein are significantly less expensive, while still providing high-speed data bandwidth within a fixed communication topology.

In one or more implementations, the computer hardware, configurations, and methods described herein reference multiple terms. For example, as used herein, an “accelerator” or “AI accelerator” refers to a computing device used to run a computational model—such as may be used in an artificial intelligence task. In one or more embodiments, an AI accelerator may include a powerful CPU or GPU. More likely, an AI accelerator may include a special-purpose computing device such as a tensor processing unit (TPU) or field-programmable gate array (FPGA) .

As used herein, an “AI accelerator tray” refers to an arrangement of AI accelerators that are networked together. For example, and as will be illustrated in greater detail below, an AI accelerator tray may include groupings of AI accelerators that are connected to each other. It follows that, as used herein, an “AI accelerator rack” refers to multiple AI accelerator trays that are also network together. A rack configuration often includes power management as well as cooling systems to ensure that the AI accelerators within the trays within the rack are adequately powered and cooled in order to perform at peak efficiency.

As used herein, a “crossbar switch” refers to a matrix of switches that connect multiple inputs to multiple outputs. In one or more embodiments, a crossbar switch allows any of a plurality of inputs to be connected to any of a plurality of outputs. In many embodiments, a crossbar switch may be fully electrical and include a serializer and deserializer such that parallel data is converted into serial data for transmission and then back into parallel data upon reception. Additionally, a crossbar switch may transfer data over Ethernet and support port multiplexing, thereby enabling multiple data streams to be managed simultaneously. In one or more embodiments, a crossbar switch is designed to handle high bandwidth data with low latency.

As used herein, “x-dimension,” “y-dimension,” and “z-dimension” refer to relative directions within an AI accelerator tray and/or AI accelerator rack. For example, x-dimension may refer to a first direction relative to an AI accelerator tray, while y-dimension may refer to a second direction relative to the AI accelerator tray. Additionally, z-dimension may refer to a third direction relative to two or more AI accelerator trays.

As used herein, “cables” refer to physical connections between AI accelerators. For example, a cable may connect AI accelerators in any of the x-dimension, the y-dimension, or the z-dimension. Additionally, a cable may connect AI accelerators across a crossbar switch in any of the x, y, or z dimensions. For example, a cable from an AI accelerator may be an input into a crossbar switch. That data connection may route through the crossbar switch to become an output from the crossbar switch that then connects forward to a different grouping of AI accelerators or loops back to the same grouping of AI accelerators.

As used herein, a “fixed AI model communication topology” refers to a plan for how data flow is managed between multiple AI accelerators. For example, the fixed AI model communication topology may be dictated by a specific AI model and may inform how data is passed among the AI accelerators within an AI accelerator tray or AI accelerator rack. As such, the fixed AI model communication topology may consider load balancing, fault tolerance, and scalability according to the requirements of the AI model that will run on the AI accelerator tray or AI accelerator rack.

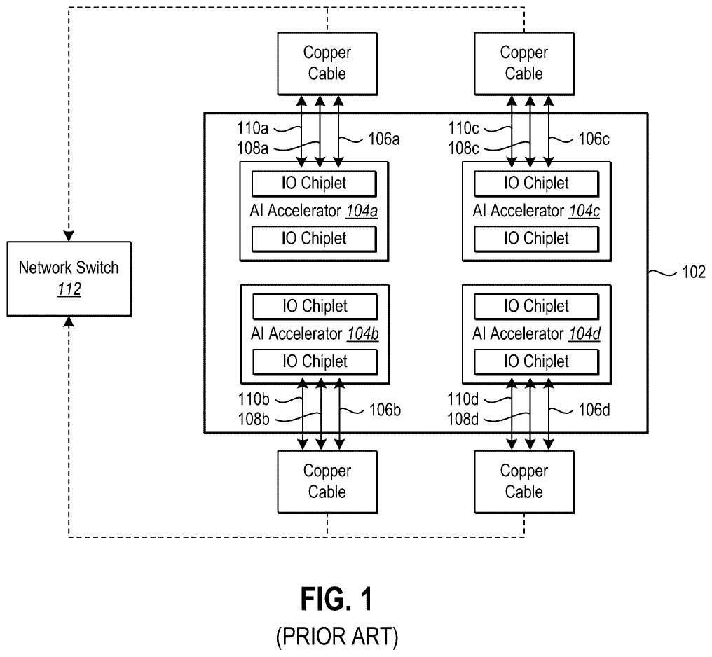

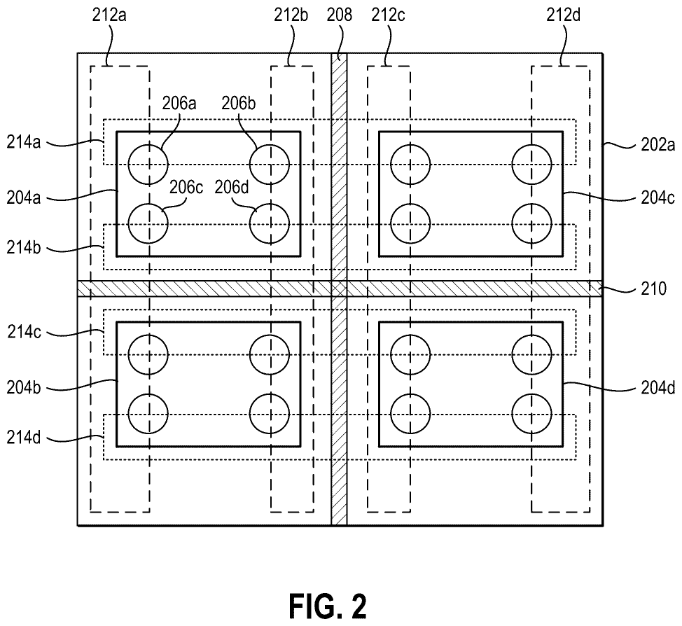

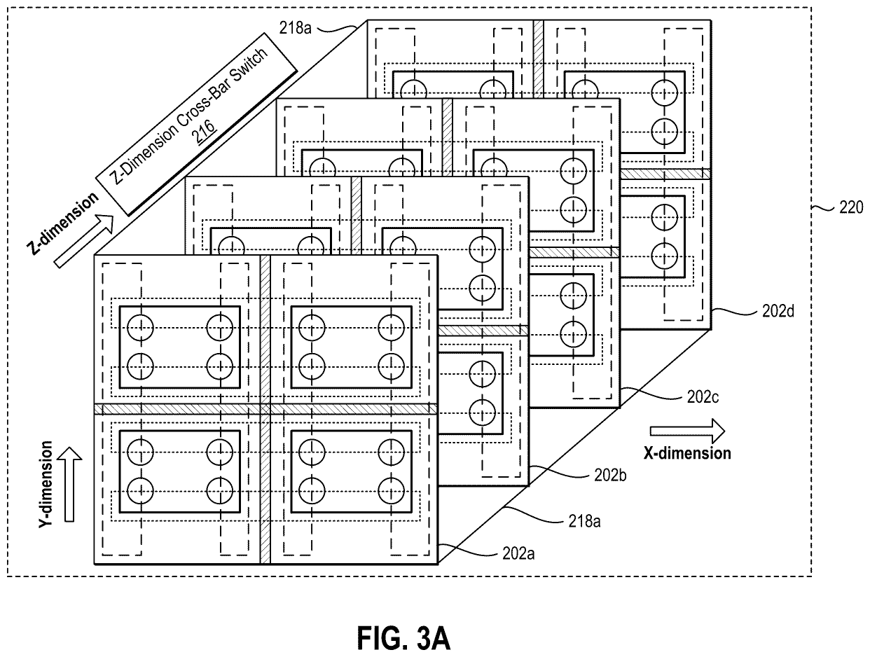

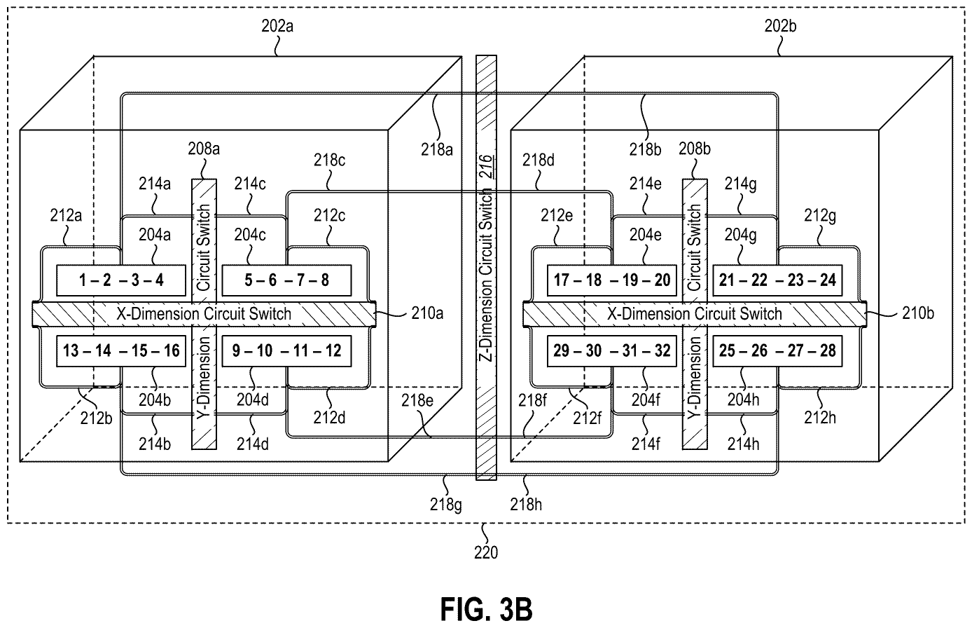

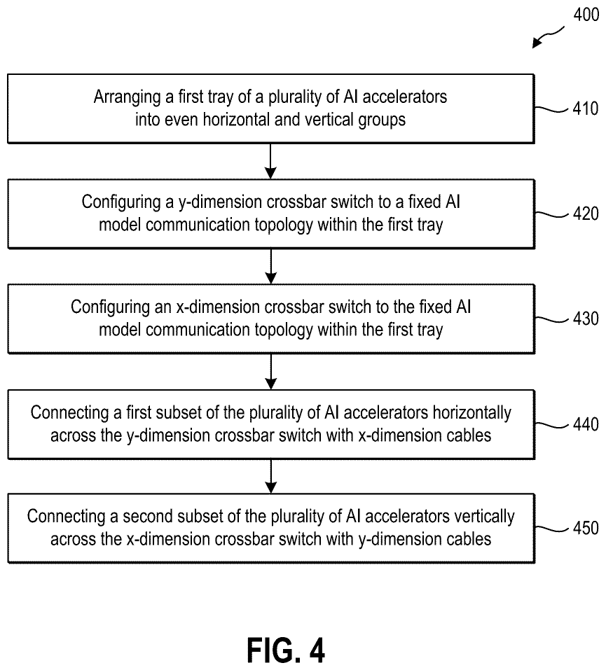

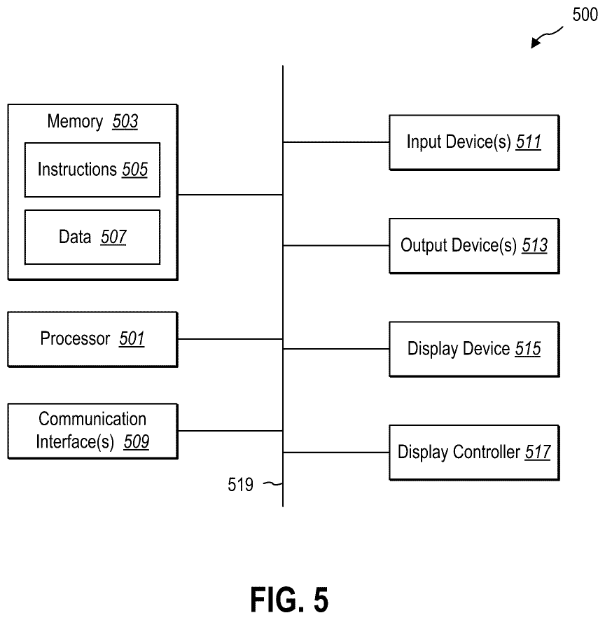

Additional details regarding example implementations of the computer hardware, configurations, and methods described herein will now be discussed in connection with the following figures. For example, FIG. 1 illustrates a typical AI accelerator tray that is generally connected to a network switch, such as discussed above. FIG. 2 illustrates an overview of an AI accelerator tray that avoids such a network switch by incorporating both x-dimension and y-dimension crossbar switches positioned among AI accelerators. FIGS. 3A and 3B illustrate an AI accelerator rack that includes a z-dimension crossbar switch connecting trays within the rack. Finally, FIG. 4 illustrates a series of acts for configuring an AI accelerator rack, while FIG. 5 illustrates certain components that may be included within a computer system.

As just mentioned, to further illustrate how AI accelerators in a typical AI accelerator tray are interconnected, FIG. 1 shows a prior art accelerator tray 102. In one or more embodiments, the prior art accelerator tray 102 includes several AI accelerators 104a, 104b, 104c, and 104d. Each of the AI accelerators 104a-104d can include input/output capabilities (e.g., such as with the IO chiplets). Furthermore, each of the AI accelerators 104a-104d may be connected to x-dimension cables 106a, 106b, 106c, and 106d, y-dimension cables 108a, 108b, 108c, and 108d, and z-dimension cables 110a, 110b, 110c, and 110d.

In one or more embodiments, the x-dimension cables 106a-106d, y-dimension cables 108a-108d, and z-dimension cables 110a-110d may connect the AI accelerators 104a-104d in a variety of ways. Regardless of how these cables connect the AI accelerators 104a-104d, as further shown in FIG. 1, the x-dimension cables 106a-106d, y-dimension cables 108a-108d, and z-dimension cables 110a-110d eventually lead to a network switch 112. In at least one embodiment, the network switch 112 receives and transmits data signals from and among the AI accelerators 104a-104d. As such, the network switch 112 acts as a traffic director—and occasional bottleneck—among the AI accelerators 104a-104d.

To improve over the typical system illustrated in FIG. 1, FIG. 2 illustrates a novel AI accelerator tray configuration that incorporates crossbar switches. For example, as shown in FIG. 2, an accelerator tray 202a includes groupings 204a, 204b, 204c, and 204d of AI accelerators. To illustrate, the grouping 204a includes AI accelerators 206a, 206b, 206c, and 206d arranged in a 2×2 formation. In additional embodiments, each of the groupings 204a-204d may include any number of AI accelerators, although most likely embodiments will include a number of AI accelerators is that is a power of two (e.g., 4, 8, 16, 32).

As further shown in FIG. 2, the accelerator tray 202a can include a y-dimension crossbar switch 208 and an x-dimension crossbar switch 210. In one or more embodiments, the y-dimension crossbar switch 208 is positioned in the y-axis direction within the accelerator tray 202a. Similarly, the x-dimension crossbar switch 210 is positioned in the x-axis direction within the accelerator tray 202a.

In at least one embodiment, the y-dimension crossbar switch 208 and the x-dimension crossbar switch 210 are configured to a fixed AI model communication topology. For example, the y-dimension crossbar switch 208 and the x-dimension crossbar switch 210 may be co-designed with a computational model that will run on the AI accelerators within the accelerator tray 202a. To illustrate, the y-dimension crossbar switch 208 and the x-dimension crossbar switch 210 may be configured to the fixed AI model communication topology such that every cable that is input into either the y-dimension crossbar switch 208 or the x-dimension crossbar switch 210 has a specific output from the y-dimension crossbar switch 208 or the x-dimension crossbar switch 210. To ensure this mapping of inputs to outputs, each of the y-dimension crossbar switch 208 and the x-dimension crossbar switch 210 may have an internal matrix of switches that are configured to ensure that this mapping does not change. In at least one embodiment, the fixed A I model communication topology informs this mapping through the internal matrix of switches for both the y-dimension crossbar switch 208 and the x-dimension crossbar switch 210 to ensure that traffic is routed through these switches as needed by the computational model that will run across the AI accelerators within the accelerator tray 202a. As such, the y-dimension crossbar switch 208 and the x-dimension crossbar switch 210 can operate without software oversight.

As further shown in FIG. 2, the accelerator tray 202a includes x-dimension cables 214a, 214b, 214c, and 214d that connect the AI accelerators across the groupings 204a-204d. For example, the x-dimension cables 214a-214d connect the AI accelerators horizontally across the y-dimension crossbar switch 208. As such, the y-dimension crossbar switch 208 is preconfigured to feed-forward or circle back data signals across the AI accelerators horizontally or in the x-direction.

Similarly, as shown in FIG. 2, the accelerator tray 202a includes y-dimension cables 212a, 212b, 212c, 212d that connect the AI accelerators across the groupings 204a-204d vertically. For example, the y-dimension cables 212a-212d connect the AI accelerators within the accelerator tray 202a in the y-dimension across the x-dimension crossbar switch 210. As such, the x-dimension crossbar switch 210 is preconfigured to feed-forward or circle back data signals across the AI accelerators vertically or in the y-direction.

In addition to increasing the accuracy of data transmission while reducing the footprint of data traffic control within an AI accelerator tray, the computer hardware, configurations, and methods described herein can perform the same tasks across multiple AI accelerator trays within an AI accelerator rack. For example, as shown in FIG. 3A, an AI accelerator rack 220 can include multiple AI accelerator trays 202a, 202b, 202c, 202d. In one or more embodiments, each AI accelerator tray 202a-202d includes the same number of AI accelerators (e.g., as with the AI accelerators 206a-206d) in the same groupings (e.g., as with the groupings 204a-204d) as illustrated in FIG. 2. Additionally, each AI accelerator tray 202a-202d further includes the same x-dimension cables 214a-214d and y-dimension cables 212a-212d across the same y-dimension crossbar switch 208 and x-dimension crossbar switch 210, respectively, as illustrated in FIG. 2. In additional embodiments, the AI accelerator rack 220 can include any number of AI accelerator trays. Similarly, each AI accelerator tray within the AI accelerator rack 220 can include any number of groupings of any number of AI accelerators.

To enable data transmission from one A I accelerator tray 202a-202d to the next, the AI accelerator rack 220 shown in FIG. 3A further includes at least one z-dimension crossbar switch 216. For example, as shown in FIG. 3A, the AI accelerator rack 220 can include the at least one z-dimension crossbar switch 216 that connects the AI accelerator trays 202a-202d via one or more z-dimension cables 218a, 218b. In one or more embodiments, the at least one z-dimension crossbar switch 216 is further configured to the same fixed AI model communication topology to which the y-dimension crossbar switch 208 and the x-dimension crossbar switch 210 in each of the AI accelerator trays 202a-202d are configured.

The use of the at least one z-dimension crossbar switch 216 is further illustrated in an example portrayed in FIG. 3B. For example, as shown in FIG. 3B, each of the trays 202a, 202b can be configured in a cuboid. In this configuration, each of the trays 202a, 202b has the groupings 204a-204h of AI accelerators with y-dimension cables 212a-212h connecting the AI accelerators vertically across the x-dimension crossbar switches 210a, 210b, and x-dimension cables 214a-214h connecting the AI accelerators horizontally across the y-dimension crossbar switches 208a, 208b.

Furthermore, as shown in FIG. 3B, the AI accelerator rack 220 can include the z-dimension crossbar switch 216 between the accelerator tray 202a and the accelerator tray 202b. The at least one z-dimension crossbar switch 216 can be connected to the groupings 204a-204h of AI accelerators via the z-direction cables 218a, 218b, 218c, 218d, 218e, 218f, 218g, and 218h.

In one or more embodiments, the positioning of the y-dimension crossbar switches 208a, 208b and associated x-dimension cables 214a-214h, the x-dimension crossbar switches 210a, 210b and associated y-dimension cables 212a-212h, the z-dimension crossbar switch 216 and associated z-dimension cables 218a-218h, increases the connectivity and transmission speed of the AI accelerators within the AI accelerator rack 220. For example, the illustrated interconnections between the AI accelerators and the y-dimension crossbar switches 208a, 208b, the x-dimension crossbar switches 210a, 210b, and the z-dimension crossbar switch 216 ensure that data can be transmitted forward in any direction. Similarly, the illustrated interconnections between the AI accelerators and the crossbar switches ensure that data can be looped back in any direction. In one or more embodiments, every AI accelerator within the AI accelerator rack 220 is within one crossbar hop away from its destination.

As mentioned above, FIG. 4 illustrates an example series of acts 400 for configuring an AI accelerator rack. While FIG. 4 illustrates acts according to one or more embodiments, alternative embodiments may omit, add to, reorder, and/or modify any of the acts shown in FIG. 4. The acts of FIG. 4 can be performed as part of a method. Alternatively, a non-transitory computer-readable medium can include instructions that, when executed by one or more processors, cause a computing device to perform the acts of FIG. 4. In still further embodiments, a system can perform the acts of FIG. 4.

As illustrated in FIG. 4, the series of acts 400 includes an act 410 of arranging a first tray of a plurality of AI accelerators into even horizontal and vertical groups.

As further illustrated in FIG. 4, the series of acts 400 includes an act 420 of configuring a y-dimension crossbar switch to a fixed AI model communication topology within the first tray. For example, configuring the y-dimension crossbar switch to the fixed AI model communication topology can include configuring an internal matrix of switches within the y-dimension crossbar switch such that y-dimension crossbar switch inputs are connected to y-dimension crossbar switch outputs as dictated by the fixed AI model communication topology.

As further illustrated in FIG. 4, the series of acts 400 includes an act 430 of configuring an x-dimension crossbar switch to the fixed AI model communication topology within the first tray. For example, configuring the x-dimension crossbar switch to the fixed AI model communication topology can include configuring an internal matrix of switches within the x-dimension crossbar switch such that x-dimension crossbar switch inputs are connected to x-dimension crossbar switch outputs as dictated by the fixed AI model communication topology.

As further illustrated in FIG. 4, the series of acts 400 includes an act 440 of connecting a first subset of the plurality of AI accelerators horizontally across the y-dimension crossbar switch with x-dimension cables. Additionally, the series of acts 400 includes an act 450 of connecting a second subset of the plurality of AI accelerators vertically across the x-dimension crossbar switch with y-dimension cables. In one or more embodiments, the first subset of the plurality of AI accelerators is different from the second subset of the plurality of AI accelerators. Additionally, arranging the plurality of AI accelerators into even horizontal and vertical groups can include arranging sixteen AI accelerators into two horizontal groups of four AI accelerators each and two vertical groups of four AI accelerators each.

In one or more embodiments, the series of acts 400 can further include acts of configuring a second tray of AI accelerators, configuring a z-dimension crossbar switch to the fixed AI model communication topology, and connecting the first tray and the second tray across the z-dimension crossbar switch with z-dimension cables.

FIG. 5 illustrates certain components that may be included within a computer system 500. One or more computer systems 500 may be used to implement the various devices, components, and systems described herein.

The computer system 500 includes a processor 501. The processor 501 may be a general-purpose single-or multi-chip microprocessor (e.g., an Advanced RISC (Reduced Instruction Set Computer) Machine (ARM) ), a special purpose microprocessor (e.g., a digital signal processor (DSP)), a microcontroller, a programmable gate array, etc. The processor 501 may be referred to as a central processing unit (CPU). Although just a single processor 501 is shown in the computer system 500 of FIG. 5, in an alternative configuration, a combination of processors (e.g., an ARM and DSP) could be used.

The computer system 500 also includes memory 503 in electronic communication with the processor 501. The memory 503 may be any electronic component capable of storing electronic information. For example, the memory 503 may be embodied as random-access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM) memory, registers, and so forth, including combinations thereof.

Instructions 505 and data 507 may be stored in the memory 503. The instructions 505 may be executable by the processor 501 to implement some or all of the functionality disclosed herein. Executing the instructions 505 may involve the use of the data 507 that is stored in the memory 503. Any of the various examples of modules and components described herein may be implemented, partially or wholly, as instructions 505 stored in memory 503 and executed by the processor 501. Any of the various examples of data described herein may be among the data 507 that is stored in memory 503 and used during execution of the instructions 505 by the processor 501.

A computer system 500 may also include one or more communication interfaces 509 for communicating with other electronic devices. The communication interface(s) 509 may be based on wired communication technology, wireless communication technology, or both. Some examples of communication interfaces 509 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

A computer system 500 may also include one or more input devices 511 and one or more output devices 513. Some examples of input devices 511 include a keyboard, mouse, microphone, remote control device, button, joystick, trackball, touchpad, and lightpen. Some examples of output devices 513 include a speaker and a printer. One specific type of output device that is typically included in a computer system 500 is a display device 515. Display devices 515 used with embodiments disclosed herein may utilize any suitable image projection technology, such as liquid crystal display (LCD), light-emitting diode (LED), gas plasma, electroluminescence, or the like. A display controller 517 may also be provided, for converting data 507 stored in the memory 503 into text, graphics, and/or moving images (as appropriate) shown on the display device 515.

The various components of the computer system 500 may be coupled together by one or more buses, which may include a power bus, a control signal bus, a status signal bus, a data bus, etc. For the sake of clarity, the various buses are illustrated in FIG. 5 as a bus system 519.

The techniques described herein may be implemented in hardware, software, firmware, or any combination thereof, unless specifically described as being implemented in a specific manner. Any features described as modules, components, or the like may also be implemented together in an integrated logic device or separately as discrete but interoperable logic devices. If implemented in software, the techniques may be realized at least in part by a non-transitory processor-readable storage medium comprising instructions that, when executed by at least one processor, perform one or more of the methods described herein. The instructions may be organized into routines, programs, objects, components, data structures, etc., which may perform particular tasks and/or implement particular data types, and which may be combined or distributed as desired in various embodiments.

The steps and/or actions of the methods described herein may be interchanged with one another without departing from the scope of the claims. In other words, unless a specific order of steps or actions is required for proper operation of the method that is being described, the order and/or use of specific steps and/or actions may be modified without departing from the scope of the claims.

The term “determining” encompasses a wide variety of actions and, therefore, “determining” can include calculating, computing, processing, deriving, investigating, looking up (e.g., looking up in a table, a database, or another data structure), ascertaining and the like. Also, “determining” can include receiving (e.g., receiving information), accessing (e.g., accessing data in a memory) and the like. Also, “determining” can include resolving, selecting, choosing, establishing and the like.

The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element or feature described in relation to an embodiment herein may be combinable with any element or feature of any other embodiment described herein, where compatible.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

1. An artificial intelligence (AI) accelerator tray comprising:
a plurality of AI accelerators;
a y-dimension crossbar switch configured to a fixed AI model communication topology;
an x-dimension crossbar switch configured to the fixed AI model communication topology;
x-dimension cables connecting a first subset of the plurality of AI accelerators across the y-dimension crossbar switch; and
y-dimension cables connecting a second subset of the plurality of AI accelerators across the x-dimension crossbar switch.

2. The AI accelerator tray as recited in claim 1, wherein the first subset of the plurality of AI accelerators is different from the second subset of the plurality of AI accelerators.

3. The AI accelerator tray as recited in claim 1, wherein the plurality of AI accelerators comprises sixteen AI accelerators.

4. The AI accelerator tray as recited in claim 3, wherein the plurality of AI accelerators is arranged into four groups of four AI accelerators.

5. The AI accelerator tray as recited in claim 4, wherein:
the x-dimension cables connect:
a first group of four AI accelerators and a second group of four AI accelerators horizontally across the y-dimension crossbar switch, and
a third group of four AI accelerators and a fourth group of four AI accelerators horizontally across the y-dimension crossbar switch; and
the y-dimension cables connect:
the first group of four AI accelerators and the third group of four AI accelerators vertically across the x-dimension crossbar switch, and
the second group of four AI accelerators and the fourth group of four AI accelerators vertically across the x-dimension crossbar switch.

6. The AI accelerator tray as recited in claim 1, wherein each of the plurality of AI accelerators comprises a tensor processing unit.

7. The AI accelerator tray as recited in claim 1, wherein the y-dimension crossbar switch and the x-dimension crossbar switch each comprise an ethernet serializer/deserializer crossbar switch.

8. An artificial intelligence (AI) accelerator rack comprising:
a plurality of AI accelerator trays, each of the plurality of AI accelerator trays comprising:
a y-dimension crossbar switch configured to a fixed AI model communication topology;
an x-dimension crossbar switch configured to the fixed AI model communication topology;
x-dimension cables connecting a first subset of AI accelerators across the y-dimension crossbar switch; and
y-dimension cables connecting a second subset of AI accelerators across the x-dimension crossbar switch;
a z-dimension crossbar switch configured to the fixed AI model communication topology; and
z-dimension cables connecting the plurality of AI accelerator trays across the z-dimension crossbar switch.

9. The AI accelerator rack as recited in claim 8, wherein each of the plurality of AI accelerator trays comprise sixteen AI accelerators.

10. The AI accelerator rack as recited in claim 9, wherein AI accelerators in each AI accelerator tray are arranged into four groups of four AI accelerators.

11. The AI accelerator rack as recited in claim 10, wherein, for each AI accelerator tray:
the x-dimension cables connect:
a first group of four AI accelerators and a second group of four AI accelerators horizontally across the y-dimension crossbar switch, and
a third group of four AI accelerators and a fourth group of four AI accelerators horizontally across the y-dimension crossbar switch; and
the y-dimension cables connect:
the first group of four AI accelerators and the third group of four AI accelerators vertically across the x-dimension crossbar switch, and
the second group of four AI accelerators and the fourth group of four AI accelerators vertically across the x-dimension crossbar switch.

12. The AI accelerator rack as recited in claim 8, wherein the plurality of AI accelerator trays comprises four AI accelerator trays.

13. The AI accelerator rack as recited in claim 8, wherein the x-dimension crossbar switch, the y-dimension crossbar switch, and the z-dimension crossbar switch each comprise an ethernet serializer/deserializer crossbar switch.

14. The AI accelerator rack as recited in claim 13, wherein the fixed AI model communication topology allows for both signal loop backs and signal forwarding across each of the x-dimension crossbar switch, the y-dimension crossbar switch, and the z-dimension crossbar switch.

15. A method for configuring an artificial intelligence (AI) accelerator rack comprising:
arranging a first tray of a plurality of AI accelerators into even horizontal and vertical groups;
configuring a y-dimension crossbar switch to a fixed AI model communication topology within the first tray;
configuring an x-dimension crossbar switch to the fixed AI model communication topology within the first tray;
connecting a first subset of the plurality of AI accelerators horizontally across the y-dimension crossbar switch with x-dimension cables; and
connecting a second subset of the plurality of AI accelerators vertically across the x-dimension crossbar switch with y-dimension cables.

16. The method as recited in claim 15, wherein configuring the y-dimension crossbar switch to the fixed AI model communication topology comprises configuring an internal matrix of switches within the y-dimension crossbar switch such that y-dimension crossbar switch inputs are connected to y-dimension crossbar switch outputs as dictated by the fixed AI model communication topology.

17. The method as recited in claim 15, wherein configuring the x-dimension crossbar switch to the fixed AI model communication topology comprises configuring an internal matrix of switches within the x-dimension crossbar switch such that x-dimension crossbar switch inputs are connected to x-dimension crossbar switch outputs as dictated by the fixed AI model communication topology.

18. The method as recited in claim 15, wherein the first subset of the plurality of AI accelerators is different from the second subset of the plurality of AI accelerators.

19. The method as recited in claim 15, wherein arranging the plurality of AI accelerators into even horizontal and vertical groups comprises arranging sixteen AI accelerators into two horizontal groups of four AI accelerators each and two vertical groups of four AI accelerators each.

20. The method as recited in claim 15, further comprising:
configuring a second tray of AI accelerators;
configuring a z-dimension crossbar switch to the fixed AI model communication topology; and
connecting the first tray and the second tray across the z-dimension crossbar switch with z-dimension cables.
